(19) United States
(12) Patent Application Publication
(10) Pub. No.: US 2010/0265644 A1
(43) Pub. Date: Oct. 21, 2010

(54) INTERFACE CARD SOCKET AND CIRCUIT BOARD MODULE HAVING THE SAME

(76) Inventor: Yen-Po Yu, Taipei (TW)

Correspondence Address: Muncy, Geissler, Olds & Lowe, PLLC, 4000 Legato Road, Suite 310, FAIRFAX, VA, 22033, US

(21) Appl. No.: 12/760,910

(22) Filed: Apr. 15, 2010

(30) Foreign Application Priority Data
Apr. 17, 2009 (TW) 098112905

(51) Int. Cl. G06F 1/16; H01R 12/14; H05K 7/00

(52) U.S. Cl. 361/679.02; 439/55; 361/748

(57) ABSTRACT

An interface card socket and a circuit board module having the same are disclosed. The circuit board module includes a first substrate, an interface card socket, a data processing unit and a connecting component. The interface card socket is detachably disposed on the first substrate and has a first slot. The first slot is used to connect with an interface card inserted. The connecting component is electrically connected to the data processing unit and the interface card socket. Therefore, the complexity of the trace design and the amount of the traces are reduced.

### CROSS REFERENCE TO RELATED APPLICATIONS

This Non-provisional application claims priority under 35 U.S.C. §119(a) on Patent Application No(s). 098112905 filed in Taiwan, Republic of China on Apr. 17, 2009, the entire contents of which are hereby incorporated by reference.

### BACKGROUND OF THE INVENTION

1. Field of Invention

The invention relates to a circuit board module and, more particularly, to a circuit board module having an interface card socket.

2. Related Art

With the development of integrated circuit (IC) technique, more and more electronic elements and traces are laid on a circuit board, and the integration becomes higher and higher. Therefore, how to reasonably use or manage the space on the circuit board becomes very important.

A computer motherboard has a central processing unit (CPU), a north bridge chip, a south bridge chip, active electronic elements, passive elements, input/output (I/O) ports, traces, and multiple interface card sockets. The interface card socket may be a memory card socket or an expansion interface card socket. The user may insert a memory card in the memory card socket or insert other interface cards in the expansion interface card sockets to increase the function of the motherboard. The interface card socket electrically connects to the north bridge chip or the south bridge chip via the traces on the motherboard, and then it is electrically connected to the CPU.

However, the disadvantages still exist in designing the motherboard. Firstly, there are multiple interface card specifications such as an accelerated graphic ports (AGP) interface, a peripheral component interconnect (PCI) interface and a PCI-Express (PCI-E) interface in the market. However, there is very limited space on a motherboard for various specifications of the interface card socket. Secondly, enough space is needed to insert an interface card with its large dimension, so as to avoid the interface card interfering with other electronic elements around the socket when the interface card is inserted. Thirdly, all the electronic elements such as the CPU, the north bridge chip, the south bridge chip, the active electronic elements, the passive electronic elements, the I/O ports and the interface card sockets require the traces to achieve the electrically connection. However, with the complexity of the traces layout, the space for the interface cards is limited, and thus would be inevitably arranged in an inconvenient place. Fourthly, with the regular equipment of the interface card sockets on a motherboard, certain specifications of the interface cards should be used. It means that the users cannot choose the interface cards or the interface card sockets by demand. Furthermore, if the user wants to use an interface card that no socket fits it on the motherboard, an extra expansion card has to be purchased.

To sum up, the conventional circuit board with an interface card socket does not provide a free and flexible usage, and the designer is also hard to design a circuit board meeting the user's requirement. As a result, the utility and competence of the circuit board are reduced, and the circuit board cannot meet the requirement of do-it-oneself (DIY) users, especially.

### SUMMARY OF THE INVENTION

A circuit board module in the invention includes a substrate, an interface card socket, a data processing unit and a connecting component. The interface card socket is detachably disposed on the substrate and has a first slot for connecting with an interface card. The connecting component is electrically connected to the data processing unit and the interface card socket.

In addition, the interface card socket according to the invention is cooperating with a substrate and includes a base and a first slot. The first slot is connected to the base to allow a connection of an interface card. The base is detachably disposed on the substrate.

To sum up, the interface card socket in the invention is detachably disposed on the substrate, and thus the interface card socket may be disposed freely. For example, the interface card socket may be disposed at any position of the substrate, or the interface card socket, the connecting component and the data processing unit may be disposed on different substrates. Therefore, the user may freely decide types and disposing positions of the interface card socket at his or her will, and thus the utility and expandability are improved. For example, the user may dispose an interface card socket for an interface card with large size at a position where few connecting ports disposed around to facilitate the usage of the surrounding peripheral connecting ports.

In addition, since the position for disposing the interface card socket is flexible, the interface card socket does not need the traces that electrically connected to the connecting component, and it may be connected to the connecting component via a cable or a wireless transmission manner. Therefore, both the complexity of the trace design and the amount of circuit lines on a circuit board traces are reduced.

These and other features, aspects and advantages of the present invention will become better understood with regard to the following description, appended claims, and accompanying drawings.

### BRIEF DESCRIPTION OF THE DRAWINGS

FIG. 1A is an exploded schematic diagram showing the circuit board module in a first preferred embodiment of the invention;

FIG. 1B is an schematic diagram showing the assembled circuit board module in FIG. 1A;

FIG. 2A to FIG. 2D are schematic diagrams showing different connecting manners of the interface card socket and the substrate;

FIG. 3 is a schematic diagram showing another circuit board module in a second preferred embodiment of the invention; and

FIG. 4 is a schematic diagram showing a circuit board module in a third preferred embodiment of the invention.

### DETAILED DESCRIPTION OF THE INVENTION

A circuit board module and an interface card socket in preferred embodiments of the invention are illustrated hereinbelow with relating drawings, and the same component numbers denote the same components.

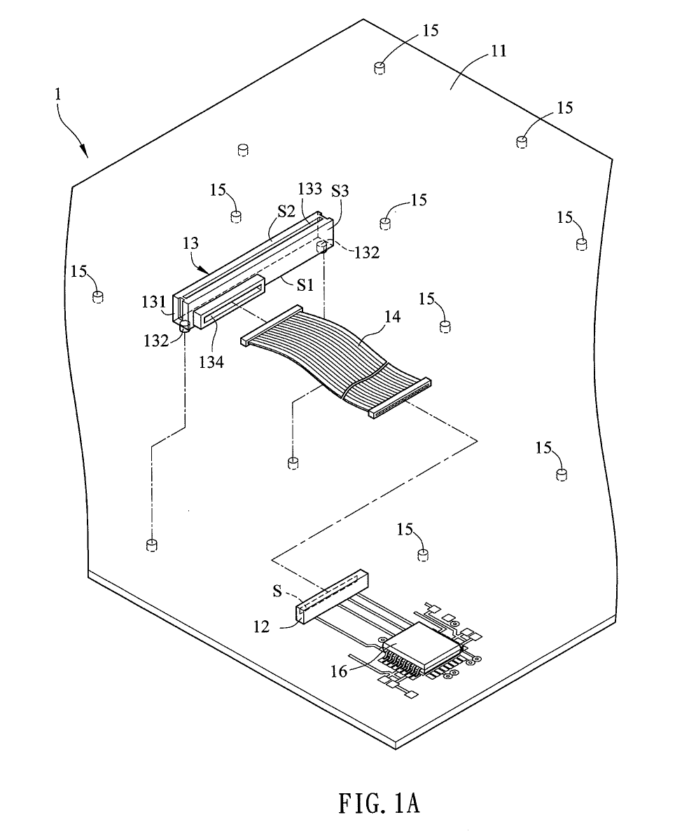

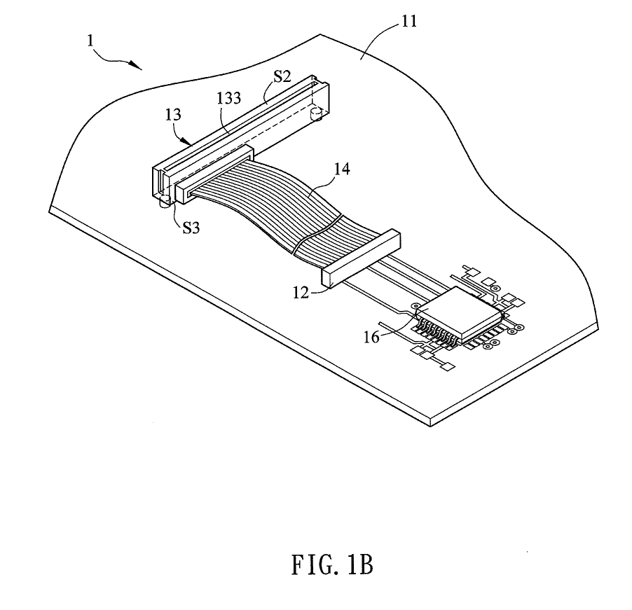

FIG. 1A and FIG. 1B are an exploded schematic diagram and an assembling diagram showing a circuit board module 1 in a first preferred embodiment of the invention, respectively. The circuit board module 1 includes a substrate 11, a connecting component 12, an interface card socket 13 and a data processing unit 16. In the embodiment, the material of the substrate 11 is not limited, and it may be resin, glass, metal, ceramic or their combinations. In addition, the substrate 11 may have traces or not according to demands. The connecting component 12 is, for example, a connector disposed on the substrate 11, and it is electrically connected to the interface card socket 13 and the data processing unit 16. The connecting component 12 also may be electronic connecting and transmitting elements with other styles, and it may be disposed on another substrate.

The interface card socket 13 is detachably disposed on the substrate 11, and it is electrically connected to a connecting component 12 via a cable 14. The cable 14 also may be a flexible printed circuit (FPC). Since the interface card socket 13 may be electrically connected to the connecting component 12 without the traces on the substrate 11, both the complexity of the traces design and the amount of the traces are reduced. In addition, since the interface card socket 13 is detachable, the user may determine the type of the interface card socket, the disposing position and the amount of the interface card sockets at his or her discretion.

The data processing unit 16 electrically connected to the connecting component 12 may be a CPU, a north bridge chip, a south bridge chip or other electronic elements with a data processing function.

In addition, the circuit board module 1 may have other elements besides the above elements according to its function. For example, to a motherboard of a computer, the circuit board module 1 may further have a CPU, a north bridge chip, a south bridge chip, active electronic elements, passive electronic elements, I/O ports and traces.

The elements on the circuit board module 1 are illustrated hereinbelow. The interface card socket 13 may be an expansion interface card socket or a memory card socket. The memory card socket may allow a connection of a memory card to increase the memory capacity, and the interface card socket may allow interface cards such as a sound card, a graphics card, a display card or an expansion card with other functions to be inserted to expand the functions. In the embodiment, the specification of the interface card socket 13 is not limited, and it may be a PCI specification, a PCI-E specification, a memory specification or an AGP specification.

The interface card socket 13 may be fastened to, engaged in, locked at or slidingly disposed on the substrate 11, and different disposing methods correspond to different corresponding structures. For example, a hook structure is used in the fastening manner, and a runner, a sliding rail or a sliding wheel are used to slidingly dispose the interface card socket 13.

In the embodiment, the interface card socket 13 includes a base 131, a positioning portion 132, a first slot 133 and a second slot 134. The positioning portion 132 is connected to the base 131 to be connected to the substrate 11. The positioning portion 132 may be a protrusion, an indentation, a hook, an embedding portion, a locking portion, a sliding portion or their combinations according to the disposing manner of the interface card socket 13 and the substrate 11. The positioning portion 132 includes two protrusions in this embodiment. The first slot 133 is connected to and the base 131 to allow an interface card (not shown) to be inserted therein. The second slot 134 is connected to the base 131 to allow one end of the cable 14 to be inserted therein. The other end of the cable 14 is inserted in a slot S of the connecting component 12. In the embodiment, the positioning portion 132 is located at a first side S1 of the base 131, and the first slot 133 is located at a second side S2 of the base 131, and the second slot 134 is disposed at a third side S3 of the base 131.

The circuit board module 1 further includes a positioning portion 15, and the positioning portion 15 is disposed on the substrate 11 to connect the interface card socket 13. The positioning portion 15 may be a protrusion, an indentation, an embedding portion, a locking portion, a sliding portion or their combinations according to the disposing manner of the substrate 11 and the interface card socket 13. The structure of the positioning portion 15 corresponds to that of the positioning portion 132, and they may be engage to each other cooperatively. The positioning portion 15 includes multiple indentations herein.

The interface card may be electrically connected to the connecting component 12 via the interface card socket 13 and the cable 14 to transmit signals, and the signal may be transmitted to the electronic elements such as the data processing unit 16 to be processed.

The circuit board module 1 may be assembled as follows. First, the user may determine the specification of the interface card socket 13 to be used. Then, one end of the cable 14 is inserted to the second slot 134 of the interface card socket 13. Afterwards, the position of the substrate 11 for disposing the interface card socket 13 is determined (that is, the corresponding positioning portion 15 is determined), and the interface card socket 13 is disposed at the positioning portion 15. Finally, the other end of the cable 14 is inserted in the slot S of the connecting component 12 (such as a connector). As a result, the user may determine the type and the position of the interface card socket 13 according to their requirements, and thus the utility and the expandability of the circuit board module 1 are improved. The sequence of the above steps is just an example, and the invention is not limited thereto. For example, the interface card socket 13 may be disposed on the substrate 11 after the cable 14 is connected to the second slot 134 and the slot S.

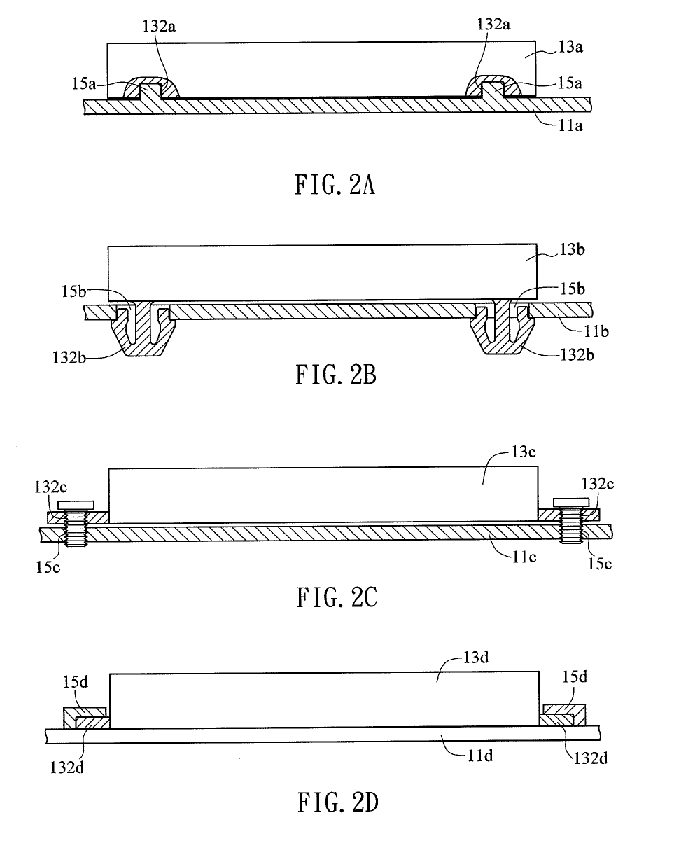

Besides the above connecting manner, the interface card socket 13 may be connected to the substrate 11 in other ways. FIG. 2A to FIG. 2D are connecting manners taken as examples. In FIG. 2A, positioning portions 132a of the interface card socket 13a include two indentations, and positioning portions 15a of the substrate includes multiple protrusions. The interface card socket 13a is fixed to the substrate 11a via the cooperation of the indentation and protrusion. As shown in FIG. 2B, a positioning portion 132b and a positioning portion 15b include a hook portion and an opening, respectively, which may be fastened to and engaged in each other. Therefore, the interface card socket 13b is connected to the substrate 11b. As shown in FIG. 2C, a positioning portion 132c and a positioning portion 15c include locking portions (such as screw holes) to be locked into each other to make the interface card socket 13c connected to the substrate 11c. As shown in FIG. 2D, the positioning portion 132d and the positioning portion 15d include sliding portions (such as a runner and a sliding part) which may be slidingly disposed relative to each other, which makes the interface card socket 13d connected to the substrate 11d.

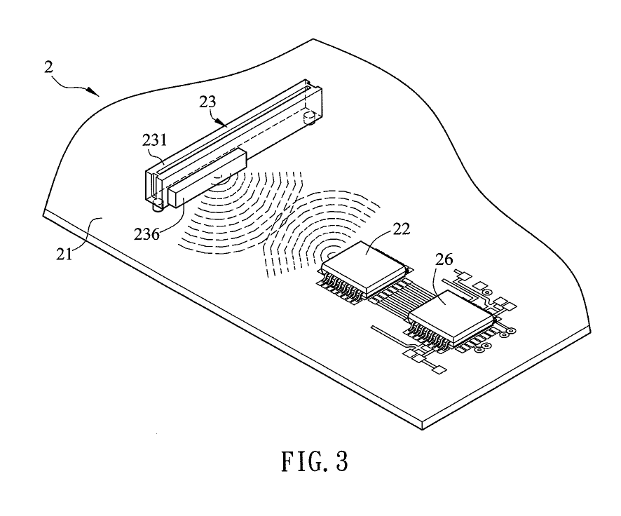

In the above embodiment, the interface card socket 13 is electrically connected to the connecting component 12 via the cable 14. In addition, FIG. 3 is a schematic diagram showing that the circuit board module 2 is electrically connected via a wireless transmission manner in a second preferred embodiment.

As shown in FIG. 3, the interface card socket 23 of the circuit board module 2 may be electrically connected to a connecting component 22 via a wireless transmission manner. In the embodiment, the connecting component 22 may be designed to be a wireless transmission chip, and the interface card socket 23 has a wireless transmission module 236. The wireless transmission module 236 may be connected to the base 231 of the interface card socket 23. The wireless transmission module 236 may transmit signals to the connecting component 22 via the wireless transmission manner. The wireless transmission manner may be Bluetooth, ultra width band (UWB), wireless universal serial bus (USB), ZigBee or laser. If the wireless transmission manner is radio transmission (such as the Bluetooth, the UWB, the wireless USB and ZigBee), the wireless transmission module 236 may include an antenna and a signal processing module. If the wireless transmission manner is laser transmission, the wireless transmission module 236 may include a light emitting diode (LED) and a light sensor.

The interface card inserted in the interface card socket 23 may transmit signal to the connecting component 22 via the wireless transmission module 236 of the interface card socket 23. The signal received by the connecting component 22 may be transmitted to the data processing unit 26, or the signal of the data processing unit 26 may be transmitted to the interface card socket 23 via the connecting component 22, and it is provided to the interface card inserted in the interface card socket 23.

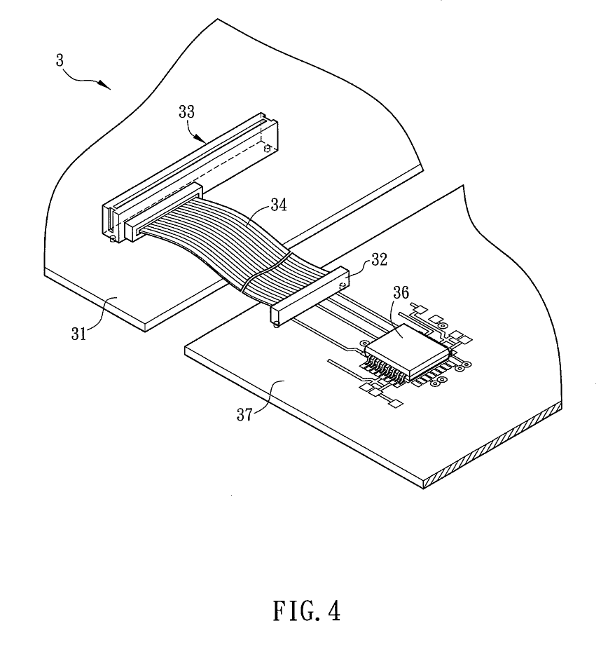

FIG. 4 is a schematic diagram showing a circuit board module 3 in a third preferred embodiment of the invention. The difference between the circuit board module 1 and the circuit board module 3 is that the circuit board module 3 further includes another substrate 37, and the connecting component 32 and the data processing unit 36 are disposed on the substrate 37. The interface card socket 33 is disposed on the substrate 31. The connecting component 32 may be electrically connected to the interface card socket 33 via the cable 34 or the wireless transmission manner, and the cable 34 is taken as an example herein. In the embodiment, the substrate 31 may not need any traces. In this embodiment, the interface card socket 33 and the substrate 31 may be integrated to be a separate component to provide higher expandability and utility. For example, the user may dispose the interface card socket 33 and the substrate 31 at a proper position such as a certain position of a casing.

In all the above embodiments, there are only an interface card socket and a connecting component in each embodiment. In other embodiments, there may be multiple interface card sockets and multiple connecting components mounted on the substrate for cooperating with the interface card sockets. For example, if the connecting component has multiple slots, one slot may cooperate with an interface card socket for usage. Additionally, if the connecting component is a wireless transmission module, the wireless transmission module also may transmit signals to multiple interface card sockets.

To sum up, the interface card socket in the invention may be detachably disposed on the substrate, and thus the interface card socket may be disposed flexibly. For example, the interface card socket may be disposed at any position of the substrate, or the interface card socket, the connecting component and the data processing unit may be disposed on different substrates. Therefore, the type and the disposing position of the interface card socket may be determined at the user's discretion, and the utility and expandability are improved. For example, the user may dispose an interface card socket for an interface card with large size at a relatively clear position where few connecting ports disposed around to facilitate the usage of the surrounding connecting ports.

In addition, since the disposing position of the interface card socket is flexible, the interface card socket does not need the traces that electrically connected to the connecting component, and it may be connected to the connecting component via the cable or the wireless transmission manner. Therefore, both the complexity of the traces design and the amount of the traces can be reduced.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. A circuit board module, comprising:
a first substrate;
an interface card socket detachably disposed on the first substrate and having a first slot for connecting with an interface card;
a data processing unit; and
a connecting component electrically connected to the data processing unit and the interface card socket.

2. The circuit board module according to claim 1, wherein the connecting component is electrically connected to the interface card socket via a cable.

3. The circuit board module according to claim 2, wherein the interface card socket further has a second slot for connecting with the cable.

4. The circuit board module according to claim 1, wherein the connecting component is electrically connected to the interface card socket via a wireless transmission manner.

5. The circuit board module according to claim 4, wherein the interface card socket further has a wireless transmission module.

6. The circuit board module according to claim 1, wherein the interface card socket and the first slot further comprises positioning portions, respectively, to engage each other.

7. The circuit board module according to claim 1, wherein the connecting component is disposed on the first substrate.

8. The circuit board module according to claim 1, further comprising:
a second substrate, wherein the connecting component and the data processing unit are disposed on the second substrate.

9. An interface card socket used cooperating with a substrate, the interface card socket comprising:
a base; and
a first slot connected to the base for connecting with an interface card, wherein the base is detachably disposed on the substrate.

10. The interface card socket according to claim 9, further comprising:
a second slot connected to the base for connecting with a cable.

11. The interface card socket according to claim 9, further comprising:
a wireless transmission module connected to the base.
